(19) United States
(12) Patent Application Publication
(10) Pub. No.: US 2004/0089927 A1
(43) Pub. Date: May 13, 2004

(54) Modularized image sensor

(76) Inventor: Hsiu Wen Tu, Hsinchu Hsien (TW)

Correspondence Address: PRO-TECHTOR INTERNATIONAL, 20775 Norada Court, Saratoga, CA, 95070-3018, US

(21) Appl. No.: 10/293,035

(22) Filed: Nov. 12, 2002

(51) Int. Cl. H01L 23/02

(52) U.S. Cl. 257/678

(57) ABSTRACT

A modularized image sensor includes a flexible/hard combination board, signal input terminals, electrical devices, a photosensitive chip and a transparent layer. The combination board has a first surface, a second surface and an opening. The signal input terminals are formed at a periphery of the opening. The electrical devices are mounted on the combination board. The photosensitive chip has a plurality of bonding pads and a photosensitive region. The photosensitive chip is mounted on the first surface with the photosensitive region exposed from the opening. The bonding pads are electrically connected to the signal input terminals. The transparent layer is mounted on the second surface and positioned above the opening, so that the photosensitive region may receive optical signals passing through the transparent layer. Accordingly, the overall volume of the modularized image sensor may be effectively reduced, and the manufacturing processes may be simplified.

### BACKGROUND OF THE INVENTION

1. Field of the Invention

The invention relates to a modularized image sensor, and in particular to a miniaturized image sensor that may be manufactured conveniently.

2. Description of the Related Art

Referring to FIG. 1, a conventional image sensor includes a substrate 10, a frame layer 18, a photosensitive chip 26, a plurality of wires 28 and a transparent layer 34. The substrate 10 has a first surface 12 formed with signal input terminals 15 and a second surface 14 formed with signal output terminals 16 which are electrically connected to a printed circuit board 17 via welding material 19. The frame layer 18 has an upper surface 20 and a lower surface 22, which is bonded to the first surface 12 of the substrate 10 to form a cavity 24 together with the substrate 10. The photosensitive chip 26 is arranged within the cavity 24 defined by the substrate 10 and the frame layer 18 and is mounted to the first surface 12 of the substrate 10. Each of the wires 28 has a first terminal 30 electrically connected to the photosensitive chip 26 and a second terminal 32 electrically connected to a corresponding signal input terminal 15 of the substrate 10. The transparent layer 34 is disposed on the upper surface 20 of the frame layer 18.

After the image sensor package is finished, it is placed on the printed circuit board 17 to cooperate with other electrical devices 33, such as active devices or passive devices, which are mounted on the printed circuit board 17. The signals are transferred via a flexible circuit board 35.

When the conventional image sensor is utilized, the printed circuit board 17 and the flexible circuit board 35 have to be used simultaneously. Therefore, the overall manufacturing processes are complicated, the assembled products have large volumes, and the miniaturized requirement cannot be satisfied.

Therefore, it is an object of the invention to provide a modularized image sensor, which may be manufactured and assembled more conveniently.

### SUMMARY OF THE INVENTION

An object of the invention is to provide a modularized image sensor, in which other electrical devices may be integrally packaged to facilitate the manufacturing processes and usage.

Another object of the invention is to provide a modularized image sensor capable of miniaturizing the products thereof.

To achieve the above-mentioned objects, a modularized image sensor of the invention includes a flexible/hard combination board, a plurality of signal input terminals, electrical devices, a photosensitive chip and a transparent layer. The combination board has a first surface, a second surface and an opening penetrating from the first surface to the second surface. The signal input terminals are formed at a periphery of the opening. The electrical devices are mounted on the combination board. The photosensitive chip has a plurality of bonding pads and a photosensitive region. The photosensitive chip is mounted on the first surface of the combination board with the photosensitive region exposed from the opening of the combination board. The bonding pads are electrically connected to the signal input terminals of the combination board. The transparent layer is mounted on the second surface of the combination board and positioned above the opening, so that the photosensitive region of the photosensitive chip may receive optical signals passing through the transparent layer.

Accordingly, the overall volume of the modularized image sensor may be effectively reduced, and the manufacturing processes may be simplified.

### BRIEF DESCRIPTION OF THE DRAWINGS

FIG. 1 is a cross-sectional view showing a conventional image sensor.

FIG. 2 is a cross-sectional view showing a modularized image sensor according to a first embodiment of the invention.

FIG. 3 is a cross-sectional view showing a modularized image sensor according to a second embodiment of the invention.

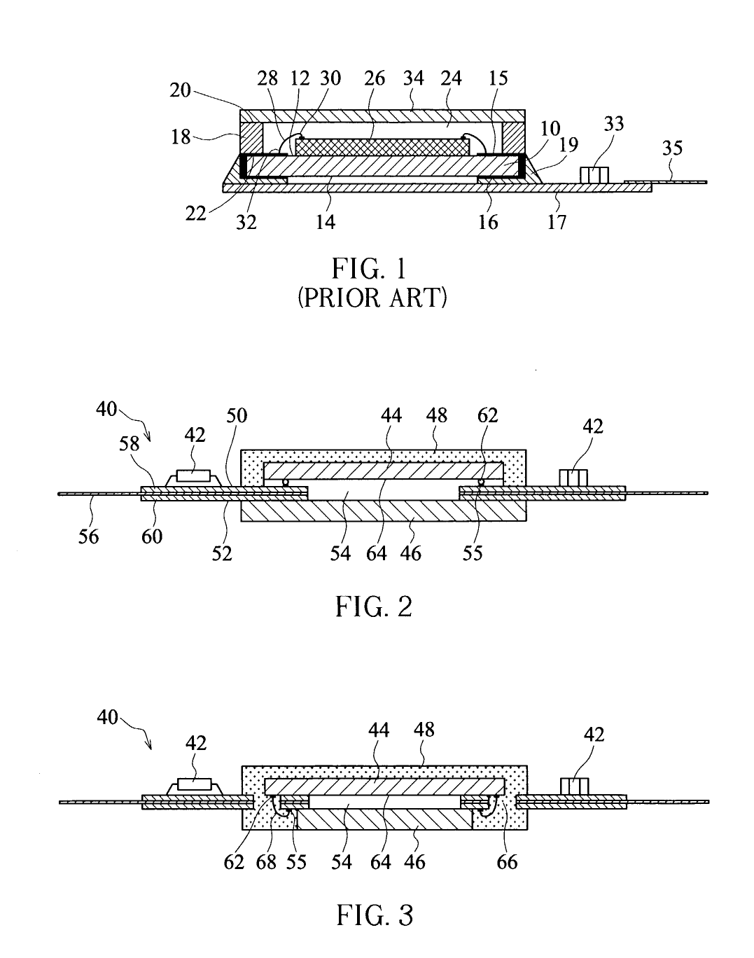

### DETAILED DESCRIPTION OF THE INVENTION

Referring to FIG. 2, a modularized image sensor according to a first embodiment of the invention includes a flexible/hard combination board 40, at least one electrical device 42, a photosensitive chip 44, a transparent layer 46 and a glue layer 48.

The flexible/hard combination board 40 has a first surface 50, a second surface 52 and an opening 54 penetrating from the first surface 50 to the second surface 52. A plurality of signal input terminals 55 are formed at the periphery of the opening 54. In this embodiment, the flexible/hard combination board 40 is composed of two hard boards 58, 60 and a flexible board 56 interposed between the two hard boards 58, 60. Signal input terminals 55 are formed on the hard board 58.

One or more than one electrical device 42, which may be an active device or a passive device, is mounted on the hard board 58.

The photosensitive chip 44 includes a plurality of bonding pads 62 and a photosensitive region 64 and is mounted on the first surface 50 with the photosensitive region 64 exposed from the opening 54. In addition, the bonding pads 62 of the photosensitive chip 44 are electrically connected to the signal input terminals 55 of the board 40 in a flip-chip manner, respectively.

The transparent layer 46 is mounted on the second surface 52 of the board 40 and is positioned above the opening 54. Thus, the photosensitive region 64 of the photosensitive chip 44 may receive optical signals passing through the transparent layer 46.

The glue layer 48 is applied to cover the photosensitive chip 44 in order to protect the photosensitive chip 44.

Referring to FIG. 3, a modularized image sensor according to the second embodiment of the invention also includes a flexible/hard combination board 40, at least one electrical device 42, a photosensitive chip 44, a transparent layer 46 and glue layer 48. Through holes 66 are formed at the periphery of the opening 54 on the flexible/hard combination board 40. When the photosensitive chip 44 is mounted on the flexible/hard combination board 40, the bonding pads 62 on the chip 44 are exposed from the through holes 66. Then, wires 68 passing through the through holes 66 are provided to electrically connect the bonding pads 62 to the signal input terminals 55 of the board 40. Thus, the photosensitive chip 44 may be electrically connected to the flexible/hard combination board 40.

In addition, the glue layer 48 is applied to the photosensitive chip 44 and filled into the through holes 66 to contact and fix the transparent layer 46.

According to the above-mentioned structure, the flexible/hard combination board 40 is used to package the photosensitive chip 44. In addition, a plurality of electrical devices 42 may be mounted to the flexible/hard combination board 40 to form a modularized image sensor. The overall volume of the modularized image sensor may be effectively reduced, and the manufacturing processes may be simplified.

While the invention has been described by way of examples and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

What is claimed is:

1. A modularized image sensor, comprising:
a flexible/hard combination board having a first surface, a second surface and an opening penetrating from the first surface to the second surface;
a plurality of signal input terminals formed at a periphery of the opening;
at least one electrical device mounted on the flexible/hard combination board;
a photosensitive chip having a plurality of bonding pads and a photosensitive region, the photosensitive chip being mounted on the first surface of the flexible/hard combination board with the photosensitive region exposed from the opening of the flexible/hard combination board, and the plurality of bonding pads being electrically connected to the signal input terminals of the flexible/hard combination board; and
a transparent layer mounted on the second surface of the flexible/hard combination board and positioned above the opening, so that the photosensitive region of the photosensitive chip may receive optical signals passing through the transparent layer.

2. The modularized image sensor according to claim 1, wherein the flexible/hard combination board includes two hard boards and a flexible board interposed between the two hard boards.

3. The modularized image sensor according to claim 2, wherein the at least one electrical device is mounted on at least one of the hard boards.

4. The modularized image sensor according to claim 1, wherein the at least one electrical device is an active device.

5. The modularized image sensor according to claim 1, wherein the bonding pads of the photosensitive chip are electrically connected to the signal input terminals of the flexible/hard combination board in a flip-chip manner.

6. The modularized image sensor according to claim 1, wherein through holes are formed at the periphery of the opening of the flexible/hard combination board, when the photosensitive chip is mounted on the flexible/hard combination board, the bonding pads are exposed from the through holes, and the bonding pads are electrically connected to the signal input terminals of the flexible/hard combination board via a plurality of wires.

7. The modularized image sensor according to claim 1, further comprising a glue layer applied to the photosensitive chip for covering the photosensitive chip.

8. The modularized image sensor according to claim 6, wherein the through holes of the flexible/hard combination board are filled with the glue layer.

9. The modularized image sensor according to claim 1, wherein the at least one electrical device is a passive device.
